(19) United States
(12) Patent Application Publication
(10) Pub. No.: US 2011/0234909 A1
(43) Pub. Date: Sep. 29, 2011

(54) RECEIVING DEVICE

(75) Inventors: Masato Ishii, Kanagawa (JP); Yoshihiro Yoshida, Kanagawa (JP); Toshimasa Adachi, Kanagawa (JP); Shigehito Saigusa, Kanagawa (JP); Takayuki Takida, Kanagawa (JP)

(73) Assignee: KABUSHIKI KAISHA TOSHIBA, Tokyo (JP)

(21) Appl. No.: 13/044,725

(22) Filed: Mar. 10, 2011

(30) Foreign Application Priority Data
Mar. 25, 2010 (JP) 2010-069399

(51) Int. Cl. H03M 1/12; H04N 5/21

(52) U.S. Cl. 348/572; 348/E05.068; 348/E05.113; 348/E05.077

(57) ABSTRACT

According to one embodiment, a receiving device includes an amplifier for amplifying signals received from the outside, a decimation filter for decimating signals converted to digital signals, a channel selection filter for selecting a desired wave included in signals from the decimation filter, and a DAGC for amplifying the desired wave selected by the channel selection filter.

### CROSS-REFERENCE TO RELATED APPLICATIONS

This application is based upon and claims the benefit of priority from the prior Japanese Patent Application No. 2010-69399, filed on Mar. 25, 2010; the entire contents of which are incorporated herein by reference.

### FIELD

An embodiment described herein relates generally to a receiving device.

### BACKGROUND

Recent television broadcast receiving devices (receiving devices) are configured to selectively receive TV (ground analog and ground digital) broadcast and CATV (cable television) broadcast. In the receiving devices, various proposals have been made so that television broadcast signals can be received well in consideration of a receiving level, distortion characteristics, and the like of the television broadcast signals. However, since it is known that distortion characteristics of a CATV signal wave (CATV mode) is more severe than distortion characteristics of TV broadcast signal wave (on air mode), various receiving devices, which can reduce power consumption while taking the distortion characteristics of the CATV mode into consideration, have been devised.

A conventional art makes a second mixer for converting digital signals to base band signals unnecessary by resampling signals using a decimation filter for converting the digital signals to the base band signals so that noise and the like caused by the second mixer is suppressed.

### BRIEF DESCRIPTION OF THE DRAWINGS

FIG. 1 is .a view explaining an example of a receiving device according to an embodiment of the present invention;

FIG. 2 is a configuration view of the receiving device shown in FIG. 1;

FIGS. 3(a) and 3(b) are views explaining an operation of a decimation filter of FIG. 2;

FIG. 4 is a view explaining a DU rate calculated by the receiving device shown in FIG. 2; and

FIG. 5 is a view showing a control unit according to the embodiment of the invention.

### DETAILED DESCRIPTION

In general, according to one embodiment, a receiving device includes an amplifier configured to amplify a signals received from the outside, a decimation filter configured to decimate signals converted to digital signals, a channel selection filter configured to select a desired wave included in signals from the decimation filter, and a DAGC configured to amplify the desired wave selected by the channel selection filter.

An exemplary embodiment of the receiving device will be explained below in detail with reference to the accompanying drawings. The present invention is not limited to the following embodiment.

### EMBODIMENT

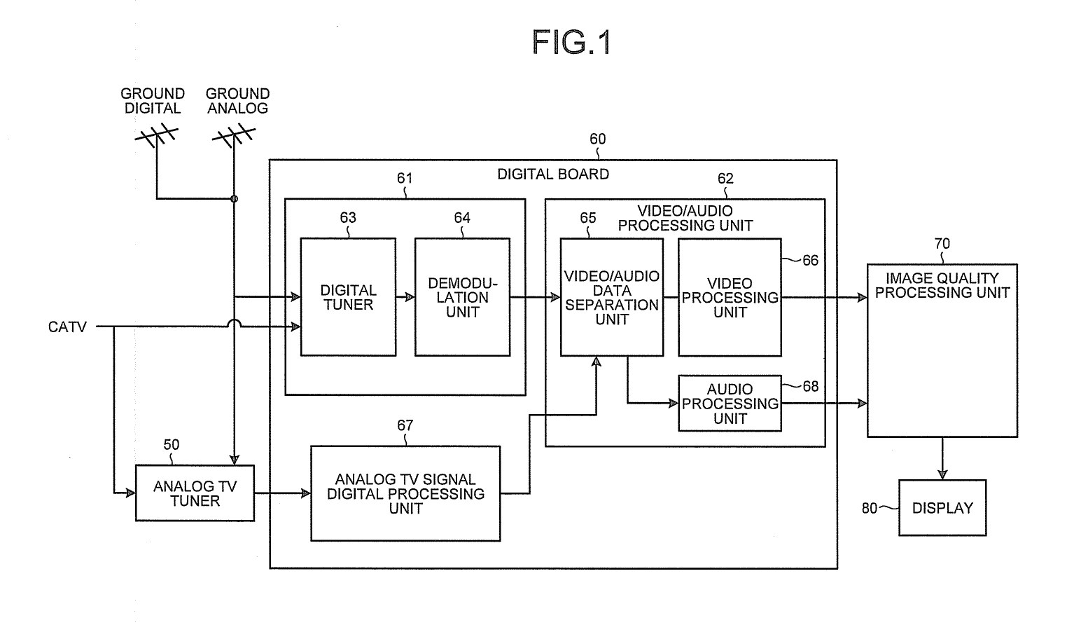

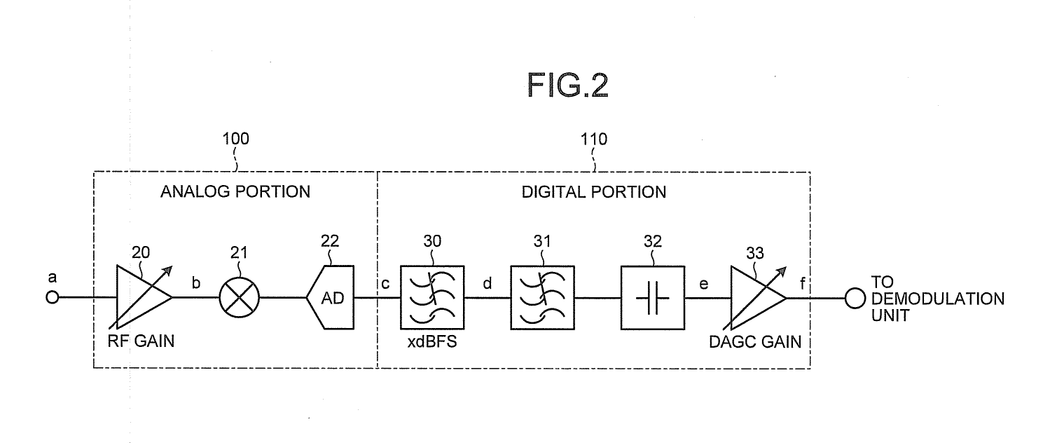

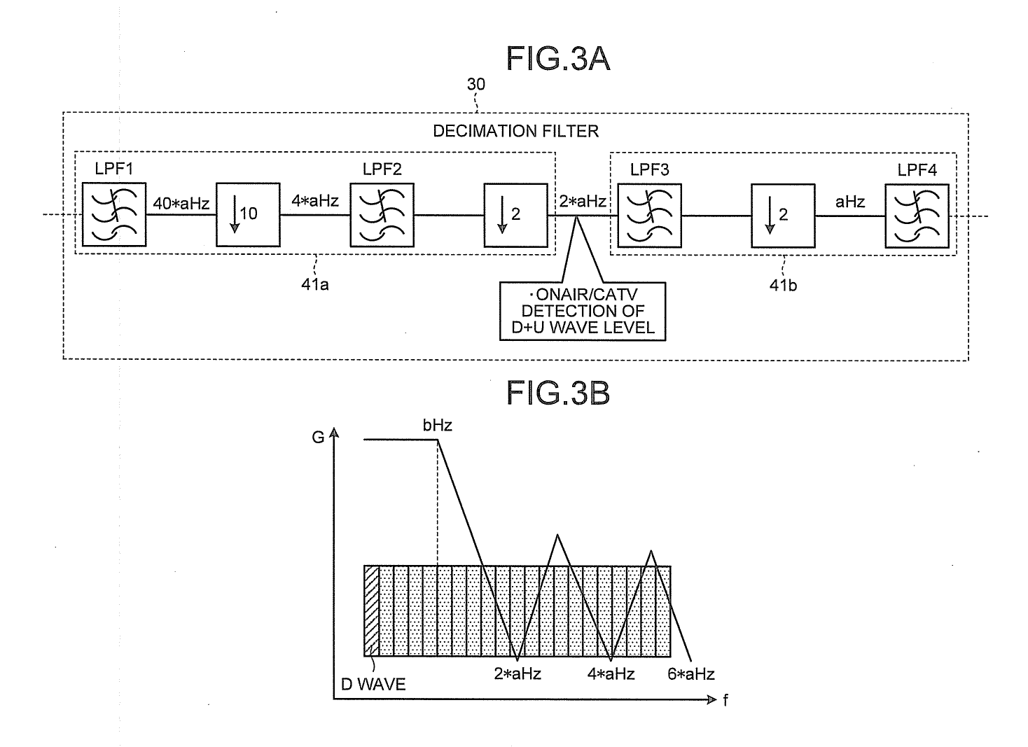

FIG. 1 is a view explaining an example of a receiving device according to an embodiment of the present invention, and FIG. 2 a configuration view of the receiving device shown in FIG. 1, and FIGS. 3(a) and 3(b) are views explaining an operation of a decimation filter of FIG. 2.

A digital board 60 shown in FIG. 1 includes a digital signal processing unit 61, a video/audio processing unit 62, and an analog TV signal digital processing unit 67. The digital signal processing unit 61 includes a digital tuner 63 and a demodulation unit 64. The digital tuner 63 is a tuner employing a direct conversion system. The digital tuner 63 is a ground digital tuner or a BS/CS digital tuner for receiving ground digital broadcast signals and CS digital broadcast signals via a ground digital broadcast signal receiving antenna as well as receiving digital broadcast signals via a CATV facility. An analog TV tuner 50 receives analog broadcast signals via a ground analog broadcast signal receiving antenna as well as receiving the analog broadcast signals via the CATV facility.

Note that FIG. 1 shows an example for receiving the digital broadcast signals and the analog broadcast signals via a receiving antenna. In addition to the example, it is possible to have a configuration for receiving broadcast signals via, for example, a coaxial cable without via the antenna.

The demodulation unit 64 demodulates digital signals from the digital tuner 63 according to a modulation type. The analog TV signal digital processing unit 67 A/D converts signals from the analog TV tuner 50 and subjects the A/D converted signals to a ghost reduction process and a YC separation.

The video/audio processing unit 62 includes a video/audio data separation unit 65 and a video processing unit 66. The video/audio data separation unit 65 separates video data and audio data from respective signals demodulated by the demodulation unit 64 according to the modulation type. The video processing unit 66 restores MPEG2 data from the video/audio data separation unit 65. An audio processing unit 68 converts audio signals from the video/audio data separation unit 65 to signals having a format which can be reproduced by a speaker mounted on a display unit 80. The signals from the video processing unit 66 are sent to the display unit 80 via a predetermined image quality processing unit 70. Note that, in FIG. 1, although the signals from the audio processing unit 68 are sent the display unit 80 via an image quality processing unit 70, it is assumed that the signals are directly sent to the speaker of the display unit 80.

The receiving device according to the embodiment of the invention is applied to both or any one of the digital tuner 63 and the analog TV tuner 50 shown in FIG. 1.

In FIG. 2, the receiving device according to the invention includes an amplifier (first amplifier) 20, a mixer 21, an analog-to-digital converter (hereinafter, simply called “AD”) 22 for converting analog signals to digital signals, a decimation filter 30, a channel selection filter 31, a DC offset canceller (hereinafter, simply called “DCOC”) 32, and a DAGC (Digital Automatic Gain Control) 33.

In the embodiment, the AD 22 is a δ-Σ A/D converter. Further, when an arbitrary number is shown by a, the AD 22 performs sampling using a predetermined sampling rate (sampling frequency) 40*a Hz. In the following explanation, a portion relating to the amplifier 20, the mixer 21, and the AD 22 is called an analog portion 100, and a portion relating to the decimation filter 30, the channel selection filter 31, the DCOC 32, and the DAGC (second the amplifier) 33 is called a digital portion 110.

A case in which the embodiment is used to the digital signal processing unit 61 will be explained below. First, the digital broadcast signals or the analog broadcast signals are input to an input terminal a. The digital broadcast signals are generally D+U waves in which a disturbing wave (hereinafter, called “U wave”) is included in a desired wave (hereinafter, called “D wave”). The amplifier 20 amplifies the D+U waves input from the input terminal a by a predetermined gain (hereinafter, called “RF gain”) and outputs the amplified signals to the mixer 21. The amplified signals are high frequency band signals. The mixer 21 is connected with a not-shown voltage control oscillator (VCO). The mixer 21 converts the amplified signals to base band signals and outputs the base band signals to the AD 22. Next, the AD 22 performs sampling of the base band signals at a frequency of 40*b Hz, converts the sampled base band signals to digital signals having a predetermined number of bits, and outputs the digital signals to the decimation filter 30.

The decimation filter 30 is a filter which lowers a sampling rate of the digital signals output from the AD 22 stepwise and repeats the sampling. As a result, the decimation filter 30 fetches signal in a predetermined range (b Hz) from the digital signals output from the AD 22. An operation of the decimation filter 30 will be described later in detail. The channel selection filter 31 is a filter for selecting signals of a predetermined band and selects and outputs a band including the D wave included in the signals output from the decimation filter 30. The DCOC 32 detects a DC component of the signals output from the channel selection filter 31 and removes the DC component. That is, the DCOC 32 cancels an offset. The DAGC 33 has a function for performing an automatic gain control (AGC), adjusts a level the signals output from the DCOC 32, and outputs the signals to the demodulation unit 64 of FIG. 1. An amplification rate of the DAGC 33 is called a DAGC gain (amplification rate of a second amplifier).

Next, the operation of the decimation filter 30 will be explained.

As shown in FIGS. 3(a) and 3(b), the decimation filter 30 includes low-pass filters (hereinafter, called LPFs). As shown in FIG. 3(a), the low-pass filters are a front stage LPF 41a and a rear stage LPF 41b. The front stage LPF 41a includes a LPF 1 and a LPF 2. The rear stage LPF 41b includes a LPF 3 and a LPF 4. The LPFs 1 to 4 realize low-pass filters by lowering a sampling rate stepwise. Note that although the four low-pass filters are exemplified here, a configuration using low-pass filters other than the four low-pass filters is also possible.

When arbitrary frequencies having a relation of a>b are shown by a Hz and b Hz, the LPF 1 performs sampling of the digital signals output from the AD 22 at a sampling rate of a frequency of the 40*a Hz. The 40*a Hz is approximately the same as the sampling rate of the AD 22. Next, the LPF 2 performs sampling at a frequency of 4*a Hz which is one tenth the sampling rate of the LPF 1. Next, the LPF 3 performs sampling at a frequency of 2*a Hz which is one half the sampling rate of the LPF 2. Finally, the LPF 4 performs sampling at a frequency of a Hz which is one half the sampling rate of the LPF 3.

The operation of the decimation filter 30 will be further explained using FIG. 3(b).

FIG. 3(b) is a view conceptually showing the D+U waves (of the base band) input to the decimation filter 30. A vertical axis of FIG. 3(b) shows a gain, and a horizontal axis shows a frequency. As shown in FIG. 3(b), the D+U waves include the D wave (of a base band) having a predetermined band and the U waves having approximately the same band as that of the D wave and having a frequency higher than that of the D wave. Further, FIG. 3(b) shows frequency characteristics of the decimation filter 30. As shown in FIG. 3(b), the decimation filter 30 has such filter characteristics that a gain is high at about b Hz or less and is lowest at predetermined frequencies of 2*a Hz, 4*a Hz, 6*a Hz, . . . .

First, the LPF 1 performs resampling of the digital signals output from the AD 22 (whose sampling rate is 40*a Hz) at 40*a Hz. Next, the LPF 2 performs resampling at, for example, a frequency (4*a Hz) which is one tenth the sampling rate of the LPF 1. Next, the LPF 3 performs resampling at, for example, a frequency (2*a Hz) which is one half the sampling rate of the LPF 2. Next, the LPF 4 performs resampling at, for example a frequency (a Hz) which is one half the sampling rate of the LPF 3.

Accordingly, in the LPF 2, although a component of 4*a Hz and components of integer times of 4*a Hz ordinarily remain in the vicinity of a DC as a desired band, since these components are removed by a decimation filter of the LPF 1, noise of integer times of 4*a Hz is not folded to the desired band of the LPF 2. Further, the LPF 3 is the same as that of the LPF 2, that is, in the LPF 3, although a component of 2*a Hz and components of integer times of 2*a Hz ordinarily remain in the vicinity of the DC band as a desired band, since these components are removed by a decimation filter of the LPF 2, noise of integer times of 2*a Hz is not folded to the desired band of the LPF 3. As described above, in the decimation filter 30, each time the sampling frequency is lowered stepwise, signals are processed in a sampling of a next stage so that unnecessary noise in a high frequency is not sampled.

Further, the AD 22 has particularly high gains at the sampling rate (40*a Hz) and in its harmonics (integer times of 40*a Hz). In contrast, the gains at the sampling rate (40*a Hz) in the AD 22 and in its harmonics (integer times of 40*a Hz) can be lowered by the operation of the decimation filter 30 described above.

Further, although a band of the D wave is selected by the channel selection filter 31 of the rear stage, to extract a proper D wave component, it is necessary to input signals including many components having a frequency lower than a predetermined frequency (b Hz in the embodiment) in consideration of filter characteristics of the channel selection filter 31. In the embodiment, the signals including the many components having the frequency lower than the predetermined frequency can be extracted by using the decimation filter 30 so that the filter characteristics of the channel selection filter 31 can be exhibited at a maximum.

Further, the invention can be used also to a superheterodyne system in addition to the direct conversion system and, in particular, when these systems are used, selection characteristics of bands can be improved by using the configuration of the invention. In addition, when the configuration of the invention is applied particularly to the direct conversion system, the configuration of the invention can exhibit a more advantageous effect. This is because although the selection characteristics of the bands tend to be more deteriorated in the direct conversion system than in the superheterodyne system, the selection characteristics of the bands can be improved by using the configuration of the invention.

How a rate of the D wave and the D+U waves (DU rate: Desired to Undesired signal rate) is calculated will be explained below. When the D+U waves at an input terminal c of the decimation filter 30 is, for example, 133 waves (D wave*1+U waves*132), the DU rate at the input terminal c is as shown below.

DU rate(c)=10log(133)≈21 dBC

It is assumed that a band (band of, for example, 2*a Hz or less) of signals, which are sampled by the LPF 2 shown in FIG. 3, is detected by a not shown detector and the detected signals (D+U waves) are about 8 waves. In this case, a level (level of the desired wave and the disturbing wave) of the D+U waves is 10log(8)≈9 dBC. In the following explanation, the level of the detected D+U waves is called “x dBFS”.

The channel selection filter 31 selects only the D wave in the signals from the decimation filter 30 and outputs the D wave to the DAGC 33. A predetermined reference level (hereinafter, simply called “REF”) is set to the DAGC 33. Accordingly, a level of the D wave at an input terminal e of the DAGC 33 is as shown below.

D wave(e)=REF−DAGC gain

The DU rate (first DU rate) in the digital portion 110 can be shown by a rate of the D wave at the input terminal e and the D+U waves detected by the decimation filter 30 as shown below.

First DU rate=(REF−DAGC gain)−x dBFS

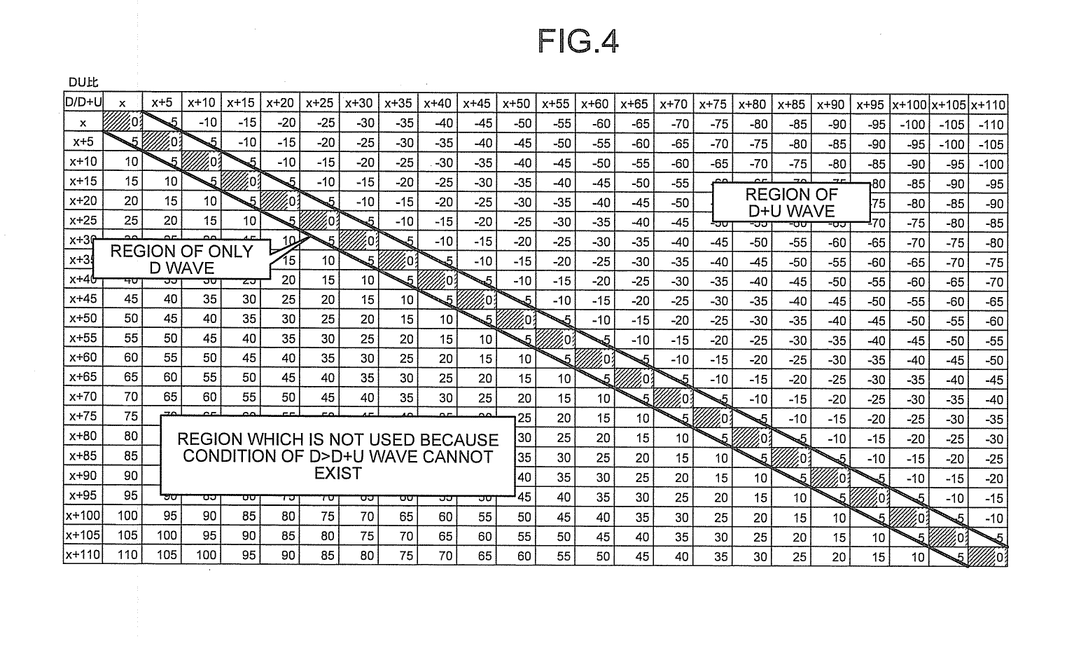

FIG. 4 is a view explaining the DU rate calculated by the receiving device shown in FIG. 2. A vertical axis shows a level of the D wave, and a horizontal axis shows a level of the D+U waves. A region surrounded by slant lines is a region of only the D wave, and the DU rate of the region is naturally 0 dBC. Although a DU rate is shown on a side lower than the region of only the D wave, the DU rate is shown for the purpose of convenience to explain that a condition of D>D+U waves cannot be established, and thus the DU rate is not actually treated. Numerical values shown on a side upper than the region of only the D wave are used in a region of the D+U waves, that is, in a region in which the numerical values are used in the on air mode and the CATV mode. Since the receiving device according to the invention applies only a part of the region of the D+U waves to the on air mode and the CATV mode, power consumption can be reduced as well as improving characteristics as compared with a case in which all the region of the D+U waves is applied to the on air mode and the CATV mode.

The DU rate (second DU rate) according to the analog portion 100 will be explained below. The amplifier 20 of FIG. 2 performs a predetermined gain adjustment to a variation of analog signals from the input terminal a. An RF gain of the amplifier 20 can be detected by a feedback terminal (not shown) of the amplifier 20. Accordingly, the level of the D wave at the input terminal a is shown as follows.

D wave(a)=D wave (e)−RF gain=(REF−DAGC gain)−RF gain

Further, the level of the D+U waves at the input terminal a is shown as follows.

D+U waves(a)=x dBFS−RF gain

Accordingly, the DU rate (second DU rate) according to the analog portion 100 is as shown below.

Second DU rate=D wave(a)−(D+U waves(a))=((REF−DAGC gain)−RF gain)−(x dBFS−RF gain)

Although the second DU rate is less accurate than the first DU rate, the second DU rate can reduce the power consumption as compared with the case in which all the region of the D+U waves is applied to the on air mode and the CATV mode.

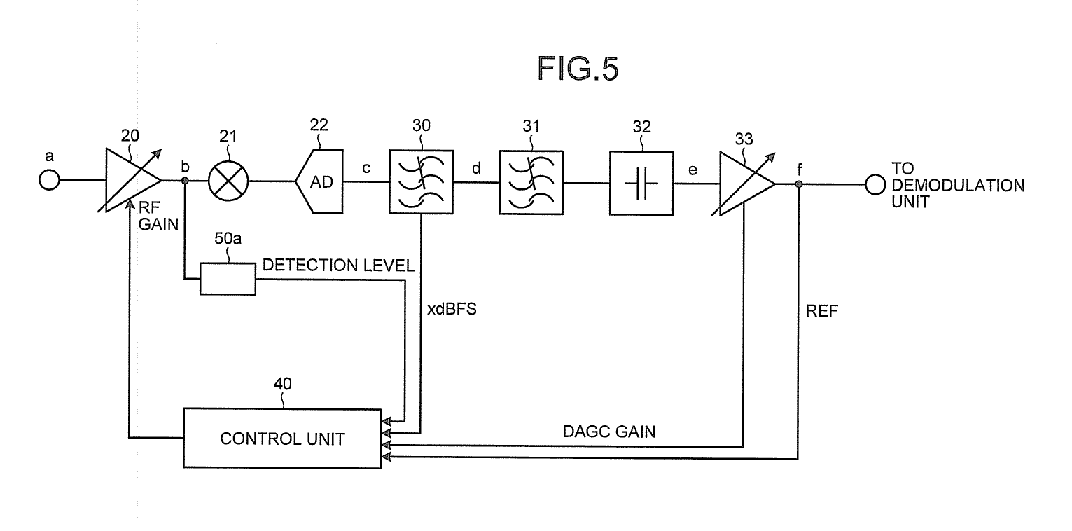

FIG. 5 is a view showing a control unit according to the embodiment of the invention. The control unit (calculation unit) 40 calculates the first DU rate described above based on the REF, the DAGC gain, and the x dBFS. Further, the control unit 40 calculates the second DU rate described above based on the REF, the DAGC gain, the x dBFS, and the RF gain.

Further, the control unit 40 functions as a control unit for controlling the gain of the amplifier 20 based on a predetermined delay point (DP:set value). The DP is a convergence point of the gain of the amplifier 20. When, for example, DP=−31 dBm is set to the control unit 40 and a detection level in a detection circuit 50a is 0 dBm, the control unit 40 controls the amplifier 20 to lower the detection level 30 dBm. Note that the DP is set to a value corresponding to the DU rates of the respective modes.

As described above, since the receiving device according to the invention includes the decimation filter 30, a certain region extracted from the region of the on air mode can be applied to the CATV mode so that the power consumption can be more reduced. Further, since the receiving device according to the invention includes the digital portion 110 and the analog portion 100, the gain can be adjusted regardless that the signals input to the input terminal a are in the CATV mode or in the on air mode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A receiving device comprising:
a first amplifier configured to amplify signals received from the outside;
a decimation filter configured to decimate signals which are supplied from the first amplifier and converted to digital signals;
a channel selection filter configured to select a desired wave included in signals from the decimation filter; and
a second amplifier configured to amplify the desired wave selected by the channel selection filter.

2. The receiving device according to claim 1, further comprising a control unit configured to calculate a first DU rate showing a rate of a level of a desired wave input to the second amplifier and a level of a desired wave and a disturbing wave detected by the decimation filter based on a reference level set to the second amplifier, an amplification rate of the second amplifier, and the level of the desired wave and the disturbing wave detected by the decimation filter.

3. The receiving device according to claim 1, further comprising a control unit configured to calculates a second DU rate showing a rate of a level of a desired wave input to the second amplifier and a level of a desired wave and a disturbing wave input to the first amplifier based on a reference level set to the second amplifier, an amplification rate of the second amplifier, a level of a desired wave and a disturbing wave detected by the decimation filter, and an amplification rate of the first amplifier.

4. The receiving device according to claim 2, wherein the control unit calculates the first DU rate and a second DU rate showing a rate of a level of a desired wave input to the second amplifier and a level of a desired wave and a disturbing wave input to the first amplifier based on a reference level set to the second amplifier, an amplification rate of the second amplifier, a level of a desired wave and a disturbing wave detected by the decimation filter, and an amplification rate of the first amplifier.

5. The receiving device according to claim 2, wherein the control unit calculates the first DU rate by subtracting the amplification rate of the second amplifier and the level of a desired wave and a disturbing wave detected from the decimation filter from the reference level.

6. The receiving device according to claim 3, wherein the control unit calculates the second DU rate by subtracting a value, which is obtained by subtracting an amplification rate of the first amplifier from the level of a desired wave and a disturbing wave detected by the decimation filter, the amplification rate of the second amplifier, and an amplification rate of the first amplifier from the reference level.

7. The receiving device according to any one of claims 2, wherein the control unit functions as a control unit configured to controls a gain of the first amplifier based on set value response to the first DU rate.

8. The receiving device according to claim 7, wherein the control unit calculates the first DU rate by subtracting the amplification rate of the second amplifier and the level of a desired wave and a disturbing wave detected from the decimation filter from the reference level.

9. The receiving device according to claims 3, wherein the control unit control a gain of the first amplifier based on set value response to the second DU rate.

10. The receiving device according to claim 9, wherein the control unit calculates the second DU rate by subtracting a value, which is obtained by subtracting an amplification rate of the first amplifier from the level of a desired wave and a disturbing wave detected by the decimation filter, the amplification rate of the second amplifier, and an amplification rate of the first amplifier from the reference level.

11. The receiving device according to claim 1, further comprising a demodulation unit that demodulates signals from the second amplifier, and a video processing unit that video process based on demodulated signals from the demodulation unit.

12. The receiving device according to claim 7, further comprising a demodulation unit that demodulates signals from the second amplifier, and a video processing unit that video process based on demodulated signals from the demodulation unit.

13. The receiving device according to claim 9, further comprising a demodulation unit that demodulates signals from the second amplifier, and a video processing unit that video process based on demodulated signals from the demodulation unit.

14. The receiving device according to claim 11, further comprising a display unit that display based on video processed signals from the video processing unit.

15. The receiving device according to claim 12, further comprising a display unit that display based on video processed signals from the video processing unit.

16. The receiving device according to claim 13, further comprising a display unit that display based on video processed signals from the video processing unit.
